(19) United States
(12) Patent Application Publication
(10) Pub. No.: US 2026/0181904 A1
(43) Pub. Date: Jun. 25, 2026

(54) SEMICONDUCTOR MEMORY DEVICE HAVING CAPACITOR STRUCTURE

(71) Applicant: SK hynix Inc., Icheon-si Gyeonggi-do (KR)

(72) Inventor: Seung Ju SHIN, Icheon-si Gyeonggi-do (KR)

(73) Assignee: SK hynix Inc., Icheon-si Gyeonggi-do (KR)

(21) Appl. No.: 19/232,541

(22) Filed: Jun. 9, 2025

(30) Foreign Application Priority Data
Dec. 19, 2024 (KR) 10-2024-0191031

(51) Int. Cl. H10B 43/35; H01L 23/522; H10B 43/20; H10B 43/40

(52) U.S. Cl. CPC H10B 43/35; H10B 43/20; H10B 43/40; H10W 20/42

(57) ABSTRACT

A semiconductor memory device includes a gate stack structure including a plurality of conductive layers, a dummy stack structure spaced apart from the gate stack structure, a vertical insulating layer disposed between the gate stack structure and the dummy stack structure, and a capacitor structure penetrating the vertical insulating layer.

### CROSS-REFERENCE TO RELATED APPLICATION

The present application claims priority under 35 U.S.C. § 119(a) to Korean patent application number 10-2024-0191031 filed on Dec. 19, 2024, in the Korean Intellectual Property Office, the entire contents of which application is incorporated herein by reference.

### BACKGROUND

### 1. Technical Field

Various embodiments of the present disclosure generally relate to a semiconductor memory device, and more particularly, to a semiconductor memory device having a capacitor structure.

### 2. Related Art

Semiconductor memory devices are applied to various electronic systems, such as small electronic devices, automobiles, medical care, and data centers, and are highly integrated and high-capacity according to user needs. Semiconductor memory devices include cell array structures and peripheral circuit structures. The cell array structure includes a plurality of memory cells for storing data, and the peripheral circuit structure constitutes a circuit for driving the plurality of memory cells. In order to improve the degree of integration of semiconductor memory devices, various technologies are being developed to efficiently utilize a limited area.

### SUMMARY

A semiconductor memory device according to an embodiment may include a gate stack structure including a plurality of conductive layers, the plurality of conductive layers extending in a plane based on a first direction and a second direction and stacked to be spaced apart from each other in a third direction crossing the plane, a dummy stack structure spaced apart from the gate stack structure in the plane, a vertical insulating layer interposed between the gate stack structure and the dummy stack structure, and a capacitor structure including a first capacitor electrode and a second capacitor electrode, the first capacitor electrode and the second capacitor electrode penetrating the vertical insulating layer and extending parallel to each other.

A semiconductor memory device according to an embodiment may include a dummy stack structure including a plurality of sacrificial insulating layers, the plurality of sacrificial insulating layers extending in a plane based on a first direction and a second direction and stacked to be spaced apart from each other in a third direction crossing the plane, a vertical insulating layer extending along a first sidewall, a second sidewall, and a third sidewall of the dummy stack structure, the first sidewall and the second sidewall facing opposite directions in the plane, the third sidewall coupling the first sidewall to the second sidewall, a gate stack structure including a plurality of conductive layers surrounding the vertical insulating layer in the plane, the plurality of conductive layers stacked to be spaced apart from each other in the third direction, and a capacitor structure penetrating the vertical insulating layer between the third sidewall of the dummy stack structure and the gate stack structure.

### BRIEF DESCRIPTION OF THE DRAWINGS

FIG. 1 is a block diagram illustrating an electronic system including a semiconductor memory device according to an embodiment of the present disclosure.

FIG. 2 is a block diagram illustrating a semiconductor memory device according to an embodiment of the present disclosure.

FIG. 3 is a diagram illustrating a cell array structure and a peripheral circuit structure of a semiconductor memory device according to an embodiment of the present disclosure.

FIG. 4 is a plan view illustrating a semiconductor memory device according to an embodiment of the present disclosure.

FIGS. 5A and 5B are cross-sectional views illustrating a semiconductor memory device according to embodiments of the present disclosure.

FIGS. 6A, 6B, 6C, 6D, 6E, 6F, and 6G are cross-sectional views illustrating various configurations formed by utilizing a method of manufacturing a semiconductor memory device according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms, but the descriptions are not limited to the examples of embodiments described in this specification.

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “on,” “side,” “upper,” “lower,” “row,” “column,” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. In addition, unless there is a special limitation on elements expressed in the singular or plural, it shall not be construed as limiting the number of elements.

Embodiments of the present disclosure may provide a semiconductor memory device capable of securing an arrangement space of a capacitor structure.

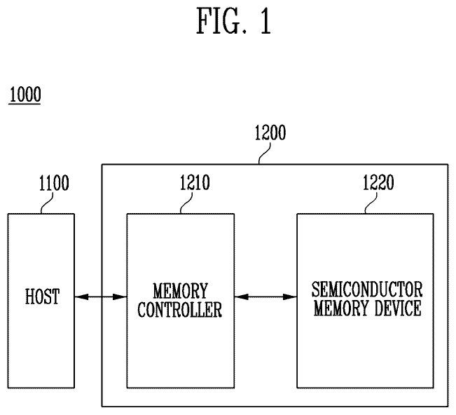

FIG. 1 is a block diagram illustrating an electronic system 1000 including a semiconductor memory device according to an embodiment of the present disclosure.

Referring to FIG. 1, the electronic system 1000 may be a computing system, a medical device, a communication device, a wearable device, a memory system, or the like. The electronic system 1000 may include a host 1100 and a storage device 1200.

The host 1100 may store data in the storage device 1200 or may read data stored in the storage device 1200 through an interface. The interface may include one or more of a Double Data Rate (DDR) interface, a Universal Serial Bus (USB) interface, a multimedia card (MC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interfaces, a small computer system interface (SCSI), an enhanced small disk interface (ESDI), an Integrated Drive Electronics (IDE) interface, a Firewire interface, a Universal Flash Storage (UFS) interface, and a Nonvolatile Memory express (NVMe) interface.

The storage device 1200 may include a memory controller 1210 and a semiconductor memory device 1220. In an embodiment, the storage device 1200 may be a storage medium, such as a solid state drive (SSD), a universal serial bus (USB) memory, or the like.

The memory controller 1210 may store data in the semiconductor memory device 1220 under the control of the host 1100 or may read data stored in the semiconductor memory devices 1220.

The semiconductor memory device 1220 may include one memory chip or a plurality of memory chips. The semiconductor memory device 1220 may store data or may output stored data under the control of the controller 1210.

The semiconductor memory device 1220 may be a non-volatile memory device. The semiconductor memory device 1220 may include a cell array structure and a peripheral circuit structure that controls operation of the cell array structure. The cell array structure may include a plurality of memory cells. Each memory cell may be a non-volatile memory cell. In an embodiment, each memory cell may be configured as a NAND flash memory cell, a ferroelectric memory cell, a variable resistance memory cell, or the like.

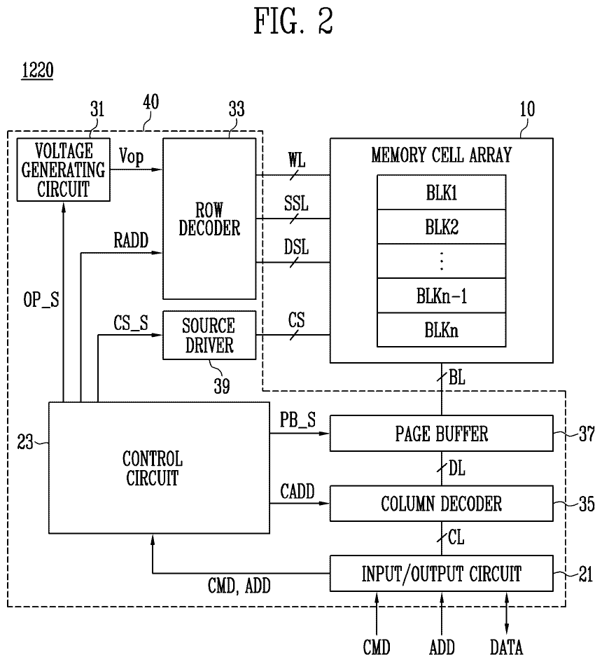

FIG. 2 is a block diagram illustrating the semiconductor memory device 1220 according to an embodiment of the present disclosure.

Referring to FIG. 2, the semiconductor memory device 1220 may include a peripheral circuit 40 having the peripheral circuit structure and a memory cell array 10 having the cell array structure. In an embodiment, the peripheral circuit 40 and the memory cell array 10 may be components of NAND flash memory devices. Hereinafter, embodiments of the present disclosure will be described based on the peripheral circuit 40 and the memory cell array 10 of the NAND flash memory device, but embodiments of the present disclosure are not limited thereto.

The peripheral circuit 40 may perform a program operation for storing data in the memory cell array 10, a read operation for outputting data stored in the memory cell arrangement 10, and an erase operation for erasing data stored in the storage cell array 10. In an embodiment, the peripheral circuit 40 may include an input/output circuit 21, a control circuit 23, a voltage generating circuit 31, a row decoder 33, a column decoder 35, a page buffer 37, and a source driver 39.

The peripheral circuit 40 may be coupled to the memory cell array 10 through a plurality of common source structures CS, a plurality of bit lines BL, a plurality of drain select lines DSL, a plurality of word lines WL, and a plurality of source select lines SSL.

The input/output circuit 21 may transmit a command CMD and an address ADD, received from a device (for example, the memory controller 1210 illustrated in FIG. 1) external to the semiconductor memory device 1220, to the control circuit 23. The input/output circuit 21 may exchange data DATA with the external device and the column decoder 35.

The control circuit 23 may output an operation signal OP_S, a row address RADD, a common source control signal CS_S, a page buffer control signal PB_S, and a column address CADD in response to the command CMD and the address ADD.

The voltage generating circuit 31 may generate various operation voltages Vop used for a program operation, a read operation, and an erase operation in response to the operation signal OP_S.

The row decoder 33 may transmit the operation voltages Vop to the plurality of drain select lines DSL, the plurality of word lines WL, and the plurality of source select lines SSL in response to the row address RADD.

The column decoder 35 may transmit the data DATA input from the input/output circuit 21 to the page buffer 37 in response to the column address CADD or may transmit the data DATA stored in the page buffer 37 to the input/output circuit 21. The column decoder 35 may exchange the data DATA with the input/output circuit 21 through the column line CL. The column decoder 35 may exchange data DATA with the page buffer 37 through the data line DL.

The page buffer 37 may control the bit line BL in response to the page buffer control signal PB_S. During the program operation, the page buffer 37 may store the data DATA received from the column decoder 35 in response to the page buffer control signal PB_S and may apply voltages to the plurality of bit lines BL based on the stored data DATA. During the read operation, the page buffer 37 may sense voltages or currents of the bit lines BL in response to the page buffer control signal PB_S and may store a sensed result.

The source driver 39 may control a voltage or a bias applied to each of the plurality of common source structures CS in response to the common source control signal CS_S received from the control circuit 23 or may ground each of the plurality the common source structures CS.

The memory cell array 10 may include a plurality of memory blocks BLK1 to BLKn (where n is a natural number equal to or greater than 2). The plurality of memory blocks BLK1 to BLKn may be coupled to the page buffer 37 through the plurality of bit lines BL. The erase operation may be controlled in units of memory blocks or the common source structure CS. At least one source layer may be coupled to the common source structure CS.

The peripheral circuit 40 may be coupled to capacitors. The capacitors may include a power capacitor that filters noise, a pump capacitor that converts voltage, or the like. In an embodiment, a capacitor capable of controlling the various operating voltages Vop to a level required for the operation of the semiconductor memory device 1220 may be coupled to the voltage generating circuit 31.

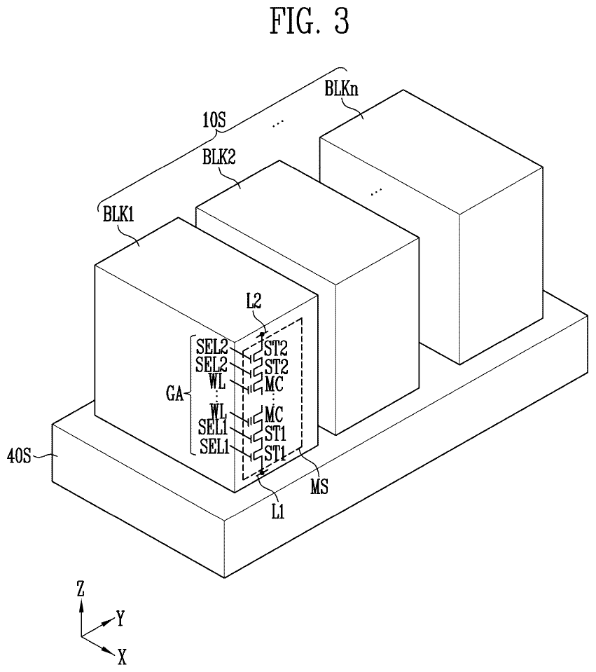

FIG. 3 is a diagram illustrating a cell array structure 10S and a peripheral circuit structure 40S of the semiconductor memory device 1220 according to an embodiment of the present disclosure.

Referring to FIG. 3, the cell array structure 10S may include the plurality of memory blocks BLK1 to BLKn (where n is a natural number equal to or greater than 2). Because a plurality of memory cells MC of each of the plurality of memory blocks BLK1 to BLKn are arranged in three dimensions, the degree of integration of memory cells within a limited area may be improved.

In an embodiment, each of the memory cells MC may be a NAND flash memory cell. In the NAND flash memory device, the plurality of memory cells MC of each of the plurality of memory blocks BLK1 to BLKn may be included in a plurality of memory cell strings MS. The plurality of memory cell strings MS may be arranged in a plurality of rows and a plurality of columns in a plane on a first direction and a second direction. For example, the first direction may correspond to an X-axis direction, the second direction may correspond to a Y-axis direction, and the plane may correspond to an XY plane. Each row of the plurality of rows may include the memory cell strings MS arranged in a line in the first direction (for example, the X-axis direction), and each column of the plurality of columns may include memory cell strings MS arranged in the second direction (for example, the Y-axis direction).

Each of the memory cell strings MS may be coupled to a first conductive layer L1, a second conductive layer L2, and a gate array GA. One of the first conductive layer L1 and the second conductive layer L2 may form a source layer, and the other may form a bit line. The first conductive layer L1 and the second conductive layer L2 may be spaced apart from each other in a third direction (for example, a Z-axis direction) that is substantially perpendicular to the plane (for example, the XY plane) and may be electrically coupled to both ends of the memory cell string MS.

The gate array GA may be disposed between the first conductive layer L1 and the second conductive layer L2. The gate array GA may include one or more first select lines SEL1, the plurality of word lines WL, and one or more second select lines SEL2 disposed to be spaced apart from each other in the third direction (for example, the Z-axis direction). One of the first select line SEL1 and the second select line SEL2 may serve as a source select line, and the other may serve as a drain select line. At least one first select line SEL1 may be disposed between the first conductive layer L1 and the plurality of word lines WL. In an embodiment, two first select lines SEL1 may be disposed between the first conductive layer L1 and the plurality of word lines WL. At least one second select line SEL2 may be disposed between the second conductive layer L2 and the plurality of word lines WL. In an embodiment, two second select lines SEL2 may be disposed between the second conductive layer L2 and the plurality of word lines WL. The memory cell string MS may include a first select transistor ST1, the plurality of memory cells MC, and a second select transistor ST2. One of the first select transistor ST1 and the second select transistor ST2 may serve as a source select transistor, and the other may serve as a drain select transistor. The first select line SEL1 may be coupled to a gate of the first select transistor ST1, the plurality of word lines WL may respectively be coupled to a plurality of gates of the plurality of memory cells MC, and the second select line SEL2 may be coupled to a gate of the second select transistor ST2. The first select transistor ST1, the plurality of memory cells MC, and the second select transistor ST2 may be coupled in series through a channel pillar. The channel pillar may include a semiconductor material electrically coupled to the first conductive layer L1 and the second conductive layer L2.

The peripheral circuit structure 40S may include transistors, registers, and the like constituting the peripheral circuit 40 illustrated in FIG. 2. Some regions of the peripheral circuit structure 40S may overlap with the cell array structure 10S in the third direction (for example, a Z-axis direction). Accordingly, the arrangement efficiency of the cell array structure 10S and the peripheral circuit structure 40S may be improved within a limited area.

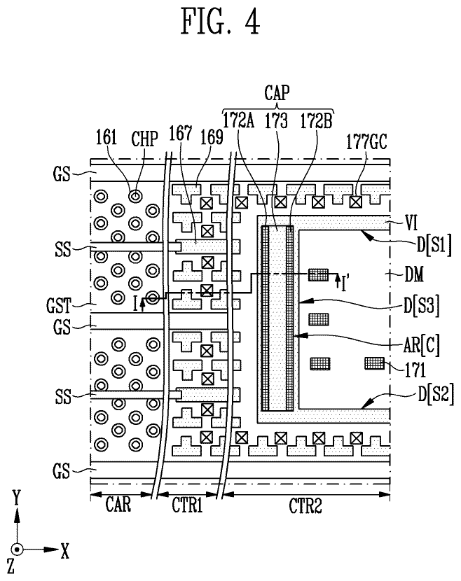

FIG. 4 is a plan view illustrating the semiconductor memory device 1220 according to an embodiment of the present disclosure.

Referring to FIG. 4, the first select line SEL1, the plurality of word lines WL, and the second select line SEL2, shown in FIG. 3, may form a plurality of conductive layers of a gate stack structure GST. The gate stack structure GST may include a cell array region CAR, a first contact region CTR1, and a second contact region CTR2.

The cell array region CAR of the gate stack structure GST may be penetrated by a plurality of channel pillars CHP and a memory layer 161. The plurality of channel pillars CHP may extend in the third direction (for example, the Z-axis direction) that is substantially perpendicular to the plane (for example, the XY plane). The memory layer 161 may be interposed between each of the channel pillars CHP and the gate stack structure GST.

The first contact region CTR1 of the gate stack structure GST may extend from the cell array region CAR in the first direction (for example, the X direction). The second contact region CTR2 of the gate stack structure GST may extend from the first contact region CTR1 in the first direction (for example, the X direction) and may be coupled to the cell array region CAR via the first contact region CTR1. In the plane (for example, the XY plane), the second contact region CTR2 may surround a region in which a plurality of peripheral circuit contact structures 171 are disposed. The plurality of peripheral circuit contact structures 171 may serve as conductive via structures for electrically coupling the plurality of memory cell strings MS of the cell array structure 10S, shown in FIG. 3, and the plurality of transistors of the peripheral circuit structure 40S, shown in FIG. 3. In an embodiment, the peripheral circuit structure 40S, shown in FIG. 3, may include a plurality of pass transistors constituting a pass circuit of the row decoder 33, shown in FIG. 1, and the gate array GA, shown in FIG. 3, may be electrically coupled to the plurality of pass transistors through the plurality of peripheral circuit contact structures 171.

The plurality of peripheral circuit contact structures 171 may be arranged to be spaced apart from each other in the first direction (for example, the X-axis direction) and the second direction (for example, the Y-axis direction) in the plane (for example, the XY plane). The plurality of peripheral circuit contact structures 171 may extend in the third direction to penetrate a dummy stack structure DM.

The dummy stack structure DM may be disposed at substantially the same level as the gate stack structure GST in the plane (for example, the XY plane). The dummy stack structure DM may include a first sidewall D[S1], a second sidewall D[S2], and a third sidewall D[S3]. The first and second sidewalls D[S1] and D[S2] may be on opposite sides of the dummy stack structure DM, the sidewalls facing opposite directions in the plane (for example, the XY plane), and the third sidewall D[S3] may couple the first and second sidewalls D[S1] and D[S2]. In the plane (for example, the XY plane), the first sidewall D[S1], the second sidewall D[S2], and the third sidewall D[S3] of the dummy stack structure DM may be surrounded by a vertical insulating layer VI.

The vertical insulating layer VI may extend along the first sidewall D[S1], the second sidewall D[S2], and the third sidewall D[S3] of the dummy stack structure DM and may be interposed between the gate stack structure GST and the dummy stack structure DM. In other words, the gate stack structure GST may surround the vertical insulating layer VI in the plane (for example, the XY plane) and may be separated from the dummy stack structure DM by the vertical insulating layer VI. The first contact region CTR1 of the gate stack structure GST may extend from the cell array region CAR toward the third sidewall D[S3] of the dummy stack structure DM, and the second contact region CTR2 of the gate stack structure GST may extend to be in parallel to each of the first sidewall D[S1] and the second sidewall D[S2] of the dummy stack structure DM.

Each of the first contact region CTR1 and the second contact region CTR2 of the gate stack structure GST may be penetrated by a plurality of support structures 167 and 169 and may be coupled to a plurality of gate contact structures 177GC. The plurality of support structures 167 and 169 may include an insulator. The boundaries of the gate stack structure GST may be formed along gate isolation structures GS. The gate isolation structures GS may correspond to slits used as a replacement path for conductive materials in the process of forming the gate stack structure GST.

Boundaries of each of the plurality of word lines WL shown in FIG. 3 may be formed along the gate isolation structures GS. The plurality of channel pillars CHP may be surrounded by each of the plurality of word lines WL, shown in FIG. 3, and may be commonly controlled by each of the plurality word lines WL, shown in FIG. 3. The plurality of channel pillars CHP may be divided into two or more groups with respect to the select line isolation structure SS. The select line isolation structure SS may extend to be in parallel to the gate isolation structures GS in the plane (for example, the XY plane) and may be disposed between adjacent gate isolation structures GS.

The select line isolation structure SS may extend from the cell array region CAR of the gate stack structure GST to the first contact region CTR1 of the gate stack structure GST and may be coupled to the first support structure 167 of the plurality of support structures 167 and 169 of the first contact region CTR1. The select line isolation structure SS may be formed in the gate stack structure GST and may include an insulating material. The select line isolation structure SS may be formed to be shorter in the third direction (for example, the Z-axis direction) than each of the gate isolation structures GS.

The channel pillars CHP of different groups may be controlled by different first select lines or different second select lines. To this end, the first select line SEL1 or the second select line SEL2, shown in FIG. 3, may have a boundary formed along the select line isolation structure SS to surround a corresponding group, among the groups of the plurality of channel pillars CHP but not the rest of the groups.

The plurality of gate contact structures 177GC may include first conductive via structures and second conductive via structures. Each of the first conductive via structure of the plurality of gate contact structures 177GC may be coupled to the first contact region CTR1 of the gate stack structure GST and may be electrically coupled to the first select line SEL1 or the second select line SEL2, shown in FIG. 3. The second conductive via structures of the plurality of gate contact structures 177GC may be coupled to the second contact region CTR2 of the gate stack structure GST and may be electrically coupled to the rest of the first select line SEL1, the plurality of word lines WL, and the second select line SEL2, shown in FIG. 3, that are not coupled to the first conductive via structures. The second support structures 169, disposed in each of the first contact region CTR1 and the second contact region CTR2, among the plurality of support structures 167 and 169, may be disposed around a corresponding gate contact structure 177GC.

A space between the gate stack structure GST and the dummy stack structure DM may be used as a capacitor region AR[C] in which the capacitor structure CAP is disposed. As a result, the capacitor region AR[C] may be secured within a limited area. The capacitor region AR[C] may be surrounded by a vertical insulating layer VI in the plane (for example, the XY plane). In other words, the capacitor structure CAP may penetrate the vertical insulating layer VI. In an embodiment, the capacitor structure CAP may penetrate the vertical insulating layer VI between the third sidewall D[S3] of the dummy stack structure DM and the gate stack structure GST. As a result, the arrangement space of some of the gate contact structures 177GC may be secured in a region that is parallel to each of the first sidewall D[S1] and the second sidewall D[S2] of the dummy stack structure DM.

The capacitor structure CAP may include a first capacitor electrode 172A and a second capacitor electrode 172B extending in parallel to each other. The capacitor structure CAP may further include a capacitor dielectric layer 173 interposed between the first capacitor electrode 172A and the second capacitor electrode 172B. Each of the first capacitor electrode 172A and the second capacitor electrode 172B may extend along opposite sides or boundaries of the capacitor region AR[C].

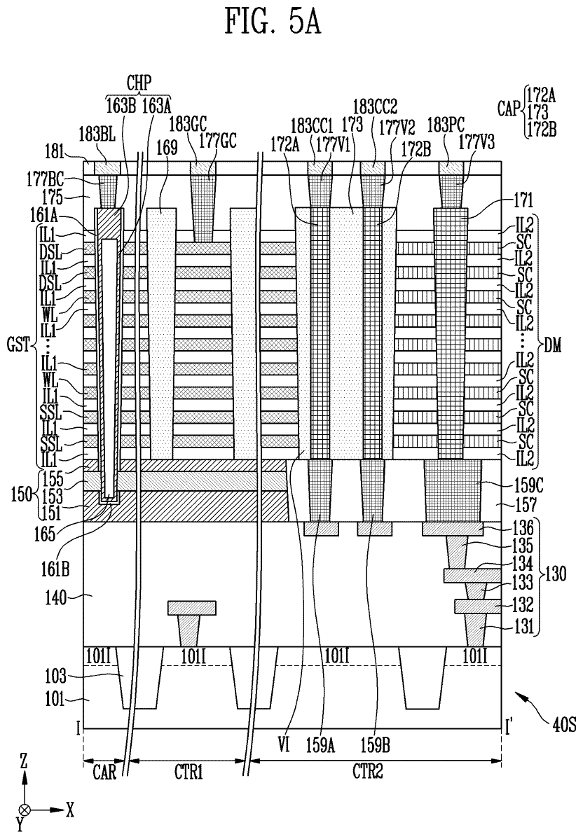

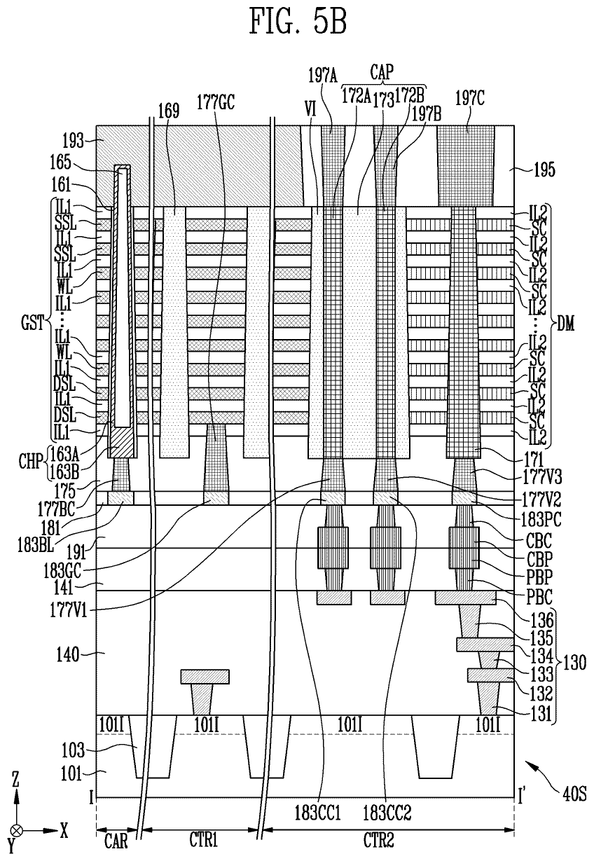

FIGS. 5A and 5B are cross-sectional views illustrating the semiconductor memory device 1220 according to embodiments of the present disclosure. FIGS. 5A and 5B each shows a cross-section of the semiconductor memory device 1220 taken along line I-I′ shown in FIG. 4.

Referring to FIGS. 5A and 5B, the peripheral circuit structure 40S of the semiconductor memory device 1220 may include a semiconductor substrate 101, transistors, a peripheral circuit-side insulating structure 140, and interconnections 130.

The semiconductor substrate 101 may include a semiconductor material. In an embodiment, the semiconductor material may include one or more of a group IV semiconductor, a group III-V compound semiconductor, and a group II-VI compound semiconductor. Group IV semiconductors may include single crystal silicon (Si), polycrystalline silicon, germanium (Ge), or silicon germanium (SiGe). Group III-V compound semiconductors may include GaAs, GaN, GaP, GaAsP, GaInAsP, AlAs, AlGa, InP, InSb, or InGaAs. Group II-VI compound semiconductors may include ZnS, ZnO, or CdS.

The semiconductor substrate 101 may further include a dielectric layer. In an embodiment, the semiconductor substrate 101 may be a silicon-on-insulator (SOI) substrate or a germanium-on-insulator (GeOI) substrate. The semiconductor substrate 101 may further include an organic material. In an embodiment, the semiconductor substrate 101 may include graphene.

The semiconductor substrate 101 may be a bulk wafer or an epitaxial layer grown through a selective epitaxial growth (SEG) method. Alternatively, the semiconductor substrate 101 may be a layer formed through a Metal Induced Lateral Crystallization (MILC) method and may partially include metal.

The semiconductor substrate 101 may have a single crystal, a polycrystalline, or an amorphous state. The semiconductor substrate 101 may include impurities of Group II, III, IV, V, or VI. In an embodiment, the semiconductor substrate 101 may include an n-well region doped with n-type impurities, a p-well region doping with p-type impurities, or an n-well region and a p-well region.

An isolation layer 103 may be disposed in the semiconductor substrate 101. The semiconductor substrate 101 may include an active region partitioned by the isolation layer 103. The transistor may include a channel region (not shown), impurity injection regions 101I, and a gate structure (not shown). The channel region and the impurity injection regions 101I may be disposed in the active region. The channel region may be disposed between the impurity injection regions 101I. Each of the impurity injection regions 101I, spaced apart from each other with the channel region therebetween, may include conductive impurities to serve as a source region or a drain region of the transistor. A majority carrier of the impurity injection regions 101I may include n-type impurities or p-type impurities depending on the electrical characteristics of the transistor. In an embodiment, the impurity injection regions 101I of a p-channel metal oxide semiconductor (PMOS) transistor may include p-type impurities as the majority carrier. In another embodiment, the impurity injection regions 101I of an n-channel metal oxide semiconductor (NMOS) transistor may include n-type impurities as the majority carrier. The gate structure may include a gate insulating layer and a gate electrode stacked on the channel region.

The transistor including the impurity injection regions 101I may be covered with the peripheral circuit-side insulating structure 140. The peripheral circuit-side insulating structure 140 may extend to cover the isolation layer 103. The peripheral circuit-side insulating structure 140 may include multilayer insulating layers.

The interconnections 130 may include conductive patterns 131, 132, 133, 134, 135, and 136, disposed in the peripheral circuit-side insulating structure 140. The conductive patterns 131, 132, 133, 134, 135, and 136 may be electrically coupled to a gate electrode (not shown) of the transistor, the impurity regions 101I, a via pattern, various signal transmission wirings, and the like.

The cell array structure of the semiconductor memory device may include a doped semiconductor structure 150 or 193, the gate stack structure GST, a bit line 183BL, a channel pillar CHP, and a memory layer 161A or 161. The gate stack structure GST may be disposed between the doped semiconductor structure 150 or 193 and the bit line 183BL, and the channel pillar CHP may pass through the gate stack structure GST and may be coupled to the doped semiconductor structure 150 or 193. A portion or all of the doped semiconductor structure 150 or 193 may serve as a source layer.

The gate stack structure GST may include a plurality of conductive layers SSL, WL, and DSL and a plurality of first interlayer insulating layers IL1. Each of the plurality of conductive layers SSL, WL, and DSL and the plurality of first interlayer insulating layers IL1 may extend in the plane (for example, the XY plane). The plurality of conductive layers SSL, WL, and DSL may be stacked to be spaced apart from each other in the third direction (for example, the Z-axis direction) crossing the plane. The plurality of first interlayer insulating layers IL1 may be alternately disposed in the third direction with the plurality of conductive layers SSL, WL, and DSL.

The plurality of conductive layers SSL, WL, and DSL may include at least one source select line SSL, at least one drain select line DSL, and the plurality of word lines WL disposed between the at least one source select line SSL and the at least one drain select line DSL. Each source select line SSL may be coupled to a gate electrode of a corresponding source select transistor, each drain select line DSL may be coupled to a gate electrode of a corresponding drain select transistor, and the plurality of word lines WL may be respectively coupled to a plurality of gates of the plurality of memory cells. Each of the plurality of conductive layers SSL, WL, and DSL may include various conductive materials, such as a doped semiconductor layer and a metal film. The doped semiconductor layer may include a doped silicon layer. The metal layer may include tungsten, copper, molybdenum, or the like. Each of the plurality of conductive layers SSL, WL, and DSL may further include a metal barrier layer. The metal barrier layer may include a metal nitride layer, and the metal nitride layer may include titanium nitride, tantalum nitride, or the like. In an embodiment, the metal barrier layer may include a double layer of titanium and titanium nitride. Each of the plurality of first interlayer insulating layers IL may include an insulating material, such as a silicon oxide layer or a silicon oxynitride layer.

The channel pillar CHP may extend vertically to penetrate the plurality of conductive layers SSL, WL, and DSL and the plurality of first interlayer insulating layers IL1 of the gate stack structure GST in the cell array region CAR. The channel pillar CHP may include a channel layer 163A. The channel layer 163A may include a semiconductor material, such as silicon (Si), germanium (Ge), or a mixture thereof, which may be used as a channel region of a memory cell string. The channel layer 163A may have a tubular shape. In this case, the channel pillar CHP may further include a core insulating layer 165 and a capping pattern 163B disposed in a central region of a tubular structure formed of the channel layer 163A. The capping pattern 163B may include a semiconductor layer doped with conductive impurities. The conductive impurities may include n-type impurities or may include n-type impurities and p-type impurities. In an embodiment, the capping pattern 163B may include n-type doped silicon that includes n-type impurities as a majority carrier.

The memory layers 161A and 161 may surround a sidewall of the channel pillar CHP. The memory layers 161A and 161 may include a tunnel insulating layer, a data storage layer, and a blocking insulating layer. Although not shown in the drawing, the tunnel insulating layer may be interposed between the channel pillar CHP and the gate stack structure GST, the data storage layer may be interposed between the tunnel insulating layer and the gate stack structure GST, and the blocking insulating layer may be interposed between the data storage layer and the gate stack structure GST. The tunnel insulating layer may include an oxide, such as silicon dioxide (SiO₂). The data storage layer may include a material layer capable of storing data that is changed using Fowler Nordheim tunneling. In an embodiment, the data storage layer may include a charge trap insulating layer or an insulating layer including conductive nanodots. The charge trap insulating layer may include a silicon nitride layer. The blocking insulating layer may include an oxide, such as silicon dioxide (SiO₂), a high-dielectric insulator having a higher dielectric constant than silicon dioxide, or the like. The high-dielectric insulating material may include an aluminum oxide film, a hafnium oxide film, or the like.

A source select transistor may be formed at an intersection between the source select line SSL and the channel layer 163A, a drain select transistor may be formed at the intersection between the drain select line DSL and the channel layer 163A, and a plurality of memory cells may be formed at intersections between the plurality of word lines WL and the channel layer 160. The source select transistor, the plurality of memory cells, and the drain select transistor may be coupled in series through the channel layer 163A of the channel pillar CHP and may form the memory cell string MS as shown in FIG. 3.

The channel pillar CHP may be coupled to the doped semiconductor structure 150 or 193 and the bit line 183BL.

The doped semiconductor structure 150 or 193 may include at least one doped semiconductor layer. The doped semiconductor layer of the doped semiconductor structure 150 or 193 may include n-type impurities or p-type impurities. In an embodiment, the doped semiconductor structure 150 or 193 may include at least one of a first conductive doped semiconductor layer including n-type impurities as a majority carrier and a second conductive doped semiconductor layer including p-type impurities as a majority carrier. The first conductive doped semiconductor layer may be provided as a source layer, and the second conductive doped semiconductor layer may be provided as a well region. The source layer of the doped semiconductor structure 150 or 193 may be in direct contact with a sidewall or bottom surface of the channel pillar CHP.

Referring to FIG. 5A, in an embodiment, a portion of a sidewall of the channel layer 163A may form a contact surface with the doped semiconductor structure 150. In an embodiment, the doped semiconductor structure 150 may include a first source layer 151, a second source layer 155, and a contact source layer 153 between the first source layer 151 and the second source layer 155. Each of the first source layer 151, the second source layer 155, and the contact source layer 153 may include a doped semiconductor layer. The channel layer 163A may extend into each of the first source layer 151, the second source layer 155, and the contact source layer 153. The memory layer 161A may extend between the second source layer 155 and the channel layer 163A. A dummy memory layer 161B may be disposed between the first source layer 151 and the channel layer 163A. The dummy memory layer 161B may include the same material as the memory layer 161A. The contact source layer 153 may be interposed between the memory layer 161A and the dummy memory layer 161B and may be in contact with the channel layer 163A.

Referring to FIG. 5B, an end of the channel layer 163A may extend into the doped semiconductor structure 193 and may form the contact surface with the doped semiconductor structures 193.

Referring to FIGS. 5A and 5B, the capping pattern 163B of the channel pillar CHP may be electrically coupled to the bit line 183BL via a bit line connection structure 177BC. The bit line connection structure 177BC may be disposed in an insulating structure 175. The insulating structure 175 may include multilayer insulating layers covering the gate stack structure GST. The bit line connection structure 177BC may include one or more conductive patterns. In an embodiment, the bit line connection structure 177BC may include a single conductive pattern. In another embodiment, the bit line connection structure 177BC may include a first conductive pattern and a second conductive pattern that are vertically overlapped with each other.

The bit line 183BL may be disposed in an insulating layer 181. The insulating layer 181 may cover the insulating structure 175.

Each of the drain select lines DSL of the gate stack structure GST in the first contact region CTR1 may be coupled to a corresponding gate contact structure 177GC. Although not shown in FIGS. 5A and 5B, each of the plurality of word lines WL and source select lines SSL of the gate stack structure GST in the second contact region CTR2 may be coupled to the corresponding gate contact structure 177GC. The gate contact structure 177GC may be electrically coupled to a gate connection line 183GC disposed in the insulating layer 181. In the second contact region CTR2, the gate stack structure GST may include a sidewall extending along the vertical insulating layer VI. Each of the first and second support structures 167 and 169, illustrated in FIG. 4, may extend vertically to penetrate the plurality of conductive layers SSL, WL, and DSL and the plurality of first interlayer insulating layers IL1 of the gate stack structure GST as in the second support structure 169, illustrated in FIGS. 5A and 5B.

The vertical insulating layer VI may be penetrated by the first capacitor electrode 172A, the second capacitor electrode 172B, and the capacitor dielectric layer 173 of the capacitor structure CAP. The first capacitor electrode 172A may be disposed closer to the gate stack structure GST than the second capacitor electrode 172B. The second capacitor electrode 172B may be disposed closer to the dummy stack structure DM than the first capacitor electrode 172A. The first capacitor electrode 172A and the second capacitor electrode 172B may include various conductive materials. Alternatively, the first capacitor electrode 172A and the second capacitor electrode 172B may include the same conductive material. The capacitor dielectric layer 173 and the vertical insulating layer VI may include various insulating materials and may include the same or different insulating materials.

The dummy stack structure DM may include the third sidewall D[S3], illustrated in FIG. 4, and the third sidewall D[S3] may extend along the vertical insulating layer VI. The dummy stack structure DM may be disposed at substantially the same level as the gate stack structure GST. The dummy stack structure DM may include a plurality of sacrificial insulating layers SC and a plurality of second interlayer insulating layers IL2. Each of the plurality of sacrificial insulating layers SC and the plurality of second interlayer insulating layers IL2 may extend in the plane (for example, the XY plane). The plurality of sacrificial insulating layers SC may be separated from each other and stacked in the third direction (for example, a Z-axis direction). The plurality of sacrificial insulating layers SC may be disposed at substantially the same levels as the plurality of conductive layers SSL, WL, and DSL, respectively. The plurality of sacrificial insulating layers SC may include an insulating material having an etching selectivity for each of the plurality of first interlayer insulating layers IL1 and the plurality of second interlayer insulating layers IL2. In an embodiment, the plurality of sacrificial insulating layers SC may include a silicon nitride layer, and the plurality of first interlayer insulating layers IL1 and the plurality of second interlayer insulating layers IL2 may include a silicon dioxide layer. The plurality of second interlayer insulating layers IL2 may be alternately disposed in the third direction (for example, a Z-axis direction) with the plurality of sacrificial insulating layers SC. The plurality of second interlayer insulating layers IL2 may be disposed at substantially the same levels as the plurality of first interlayer insulating layers IL1, respectively.

The plurality of sacrificial insulating layers SC and the plurality of second interlayer insulating layers IL2 of the dummy stack structure DM may be penetrated by the peripheral circuit contact structure 171. The peripheral circuit contact structure 171 may include various conductive materials.

The insulating structure 175 and the insulating layer 181 may extend to cover the support structure 169, the vertical insulating layer VI, the capacitor structure CAP, the peripheral circuit contact structure 171, and the dummy stack structure DM. The insulating structure 175 may be penetrated by via contacts 177V1, 177V2, and 177V3, and the insulating layer 181 may be penetrated by connection patterns 183CC1, 183CC2, and 183PC.

The via contacts 177V1, 177V2, and 177V3 may include various conductive materials. The via contacts 177V1, 177V2, and 177V3 may include a first capacitor via contact 177V1 coupled to the first capacitor electrode 172A, a second capacitor via contact 177V2 coupled to the second capacitor electrode 172B, and a peripheral circuit via contact 177V3 coupled to the peripheral circuit contact structure 171.

The connection patterns 183CC1, 183CC2, and 183PC may include various conductive materials. The connection patterns 183CC1, 183CC2, and 183PC may include a first capacitor connection pattern 183CC1 coupled to the first capacitor via contact 177V1, a second capacitor connection pattern 183CC2 coupled to the second capacitor via contact 177V2, and a peripheral circuit connection pattern 183PC coupled to the peripheral circuit via contact 177V3.

The source level insulating layer 157 or 195 may cover one surface of each of the dummy stack structure DM, the vertical insulating layer VI, and the capacitor structure CAP, the source level insulating layer 157 or 195 and insulating structure 175 covering opposite surfaces of the dummy stack structure DM, the vertical insulating layer VI, and the capacitor structure CAP. The source level insulating layer 157 or 195 may overlap with the dummy stack structure DM in the third direction (for example, a Z-axis direction). The source level insulating layer 157 or 195 may be disposed substantially at the same level as the doped semiconductor structure 150 or 193.

One of the doped semiconductor structure 150 or 193 and the bit line 183BL may be disposed adjacent to the peripheral circuit-side insulating structure 140. In an embodiment, referring to FIG. 5A, the doped semiconductor structure 150 may be disposed closer to the peripheral circuit-side insulating structure 140 than the bit line 183BL. In another embodiment, referring to FIG. 5B, the bit line 183BL may be disposed closer to the peripheral circuit-side insulating structure 140 than the doped semiconductor structure 193.

Referring to FIG. 5A, in an embodiment, processes of forming the cell array structure, such as the doped semiconductor structure 150, may be performed over the peripheral circuit-side insulating structure 140. In this case, before forming the gate stack structure GST and the dummy stack structure DM, first, second, and third source level contacts 159A, 159B, and 159C may be formed to penetrate the source level insulating layer 157. The first, second, and third source level contacts 159A, 159B, and 159C may be coupled to the first capacitor electrode 172A, the second capacitor electrode 172B, and the peripheral circuit contact structure 171, respectively, which are subsequently formed.

Referring to FIG. 5B, in an embodiment, processes that form a structure including a portion of the cell array structure, such as the gate stack structure GST, the dummy stack structure DM, the capacitor structure CAP, and the like may be performed over a sacrificial substrate that is different from the semiconductor substrate 101 for the peripheral circuit structure. The structure may be coupled to the peripheral circuit structure through a bonding process. In this case, the peripheral circuit structure may further include the peripheral circuit-side intervening insulating layer 141 over the peripheral circuit-side insulating structure 140, the peripheral circuit-side intervening insulating layer 141 including a peripheral circuit-side bonding pad PBP and a peripheral circuit-side bond contact PBC. The peripheral circuit-side bonding contact PBC may extend from the peripheral circuit-side bonding pad PBP to connect to the uppermost conductive pattern 136 of the interconnection 130. In addition, the semiconductor memory device may further include a cell-side intervening insulating layer 191 covering the insulating layer 181, the cell-side intervening insulating layer 191 including a cell-side bonding pad CBP and a cell-side bond contact CBC. The cell-side bonding contact CBC may extend from the cell-side bonding pad CBP to be coupled to conductive patterns, such as the first capacitor connection pattern 183CC1 and the second capacitor connection pattern 183CC2.

Before the bonding process, the gate stack structure GST, the memory layer 161, the channel pillar CHP, the dummy stack structure DM, the vertical insulating layer VI, the capacitor structure CAP, the peripheral circuit contact structure 171, the support structure 169, the bit line connection structure 177BC, the gate contact structure 177GC, the via contacts 177V1, 177V2, and 177V3, the insulating structure 175, the bit line 183BL, the connection patterns 183CC1, 183CC2, 183PC, the insulating layer 181, the cell-side intervening insulating layer 191, the cell-side bonding contact CBC, and the cell-side bonding pad CBP may be formed on the sacrificial substrate. Subsequently, the cell-side bonding pad CBP may be bonded to the peripheral circuit-side bonding pad PBP, and after removing the sacrificial substrate, the end of the channel layer 163A may be exposed. The exposed end of the channel layer 163A is opposite to the side that is closest to the bit line 183BL. The doped semiconductor structure 193 may be formed to be in contact with the exposed end of the channel layer 163A after exposing the end of the channel layer 163A. After the doped semiconductor structure 193 is formed, the source level insulating layer 195 may be formed so that the dummy stack structure DM, the vertical insulating layer VI, and the capacitor structure CAP, opened by the doped semiconductor structures 193, are covered. Subsequently, the first, second, and third source level contacts 197A, 197B, and 197C may be formed to penetrate the source level insulating layer 195. The first, second, and third source level contacts 197A, 197B, and 197C may be coupled to the first capacitor electrode 172A, the second capacitor electrode 172B, and the peripheral circuit via contact 177V3, respectively.

Referring to FIGS. 5A and 5B, the lengths of the first capacitor electrode 172A and the second capacitor electrode 172B according to an embodiment of the present disclosure may increase as the number of stacked conductive layers DSL, WL, and SSL of the gate stack structure GST increases. Accordingly, the facing area between the first capacitor electrode 172A and the second capacitor electrode 172B may increase in proportion to the number of stacked conductive layers DSL, WL, and SSL of the gate stack structure GST, and the capacitance of the capacitor structure CAP may be secured. The facing area may mean the area that both structures face each other. Accordingly, the operation reliability of the semiconductor memory device may be improved.

Hereinafter, in order to describe a method of forming the capacitor structure CAP such that the facing area between the first capacitor electrode 172A and the second capacitor electrode 172B may be increased in proportion to the number of stacked conductive layers DSL, WL, and SSL, a method of manufacturing the semiconductor memory device according to an embodiment will be described mainly in a region where the gate stack structure GST and the dummy stack structure DM are formed.

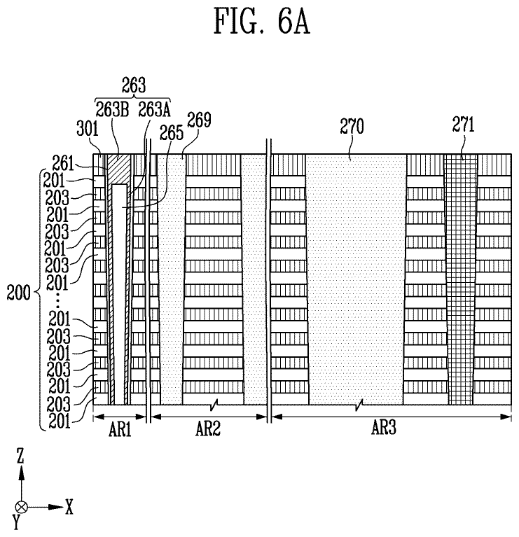

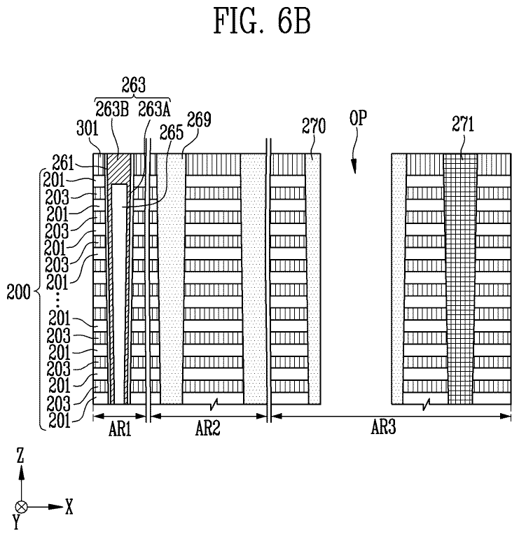

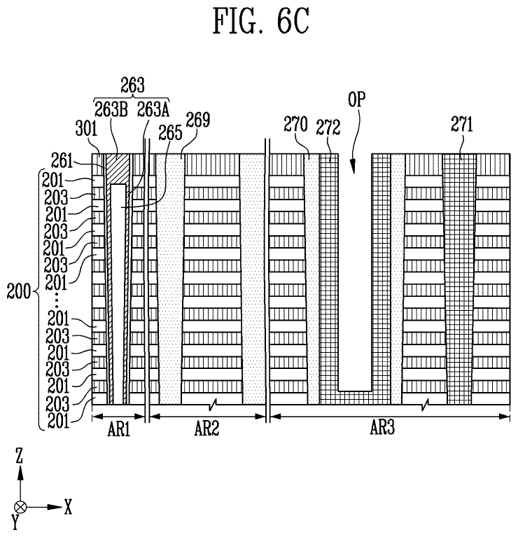

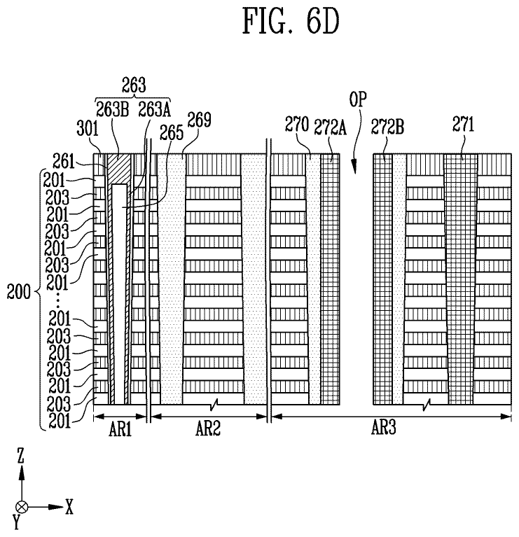

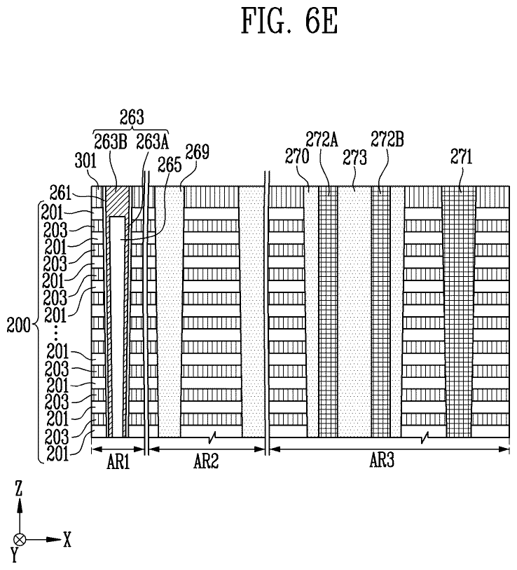

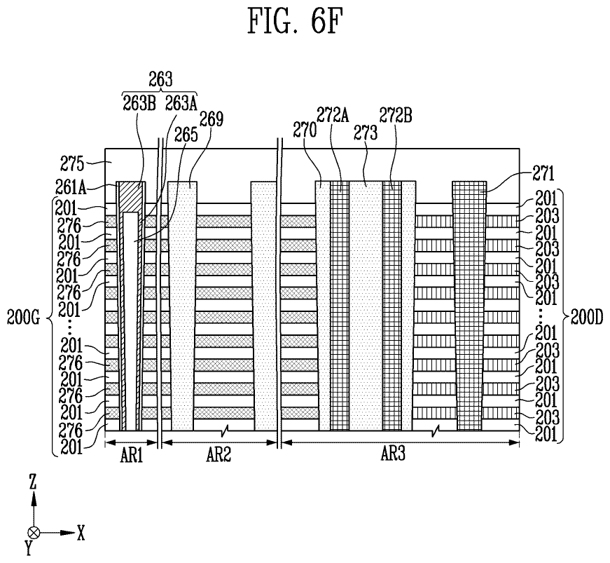

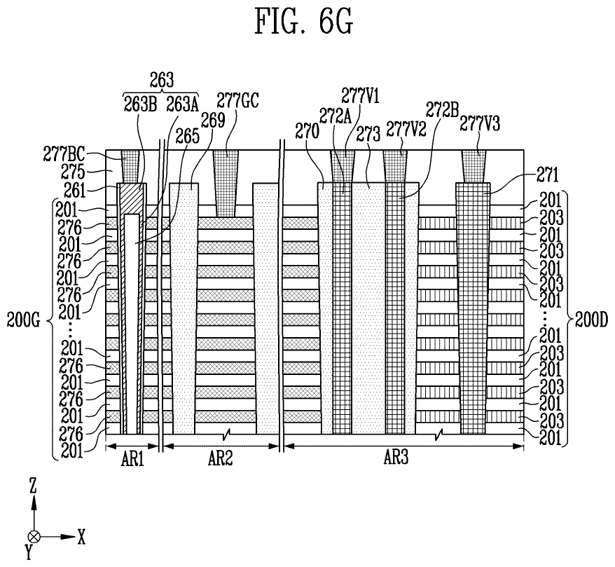

FIGS. 6A, 6B, 6C, 6D, 6E, 6F, and 6G are cross-sectional views illustrating various configurations formed by utilizing the method of manufacturing the semiconductor memory device according to an embodiment of the present disclosure.

Referring to FIG. 6A, a preliminary stack structure 200 may be formed on a lower structure (not shown). Although not shown in the drawing, the lower structure may include a peripheral circuit structure including the semiconductor substrate 101, the impurity injection regions 101I, and the interconnections 130, or the like, a pre-doped semiconductor structure including the first source layer 151 and the second source layer 155 and a source sacrificial structure therebetween, the source level insulating layer 157, and the first, second, and third source level contacts 159A, 159B, and 159C, all of which are shown in FIG. 5A. The source sacrificial structure of the pre-doped semiconductor structure may subsequently be removed, and the contact source layer 153, shown in FIG. 5A, may be formed in a region in which the source sacrificial structure is removed. In an embodiment, the lower structure may be a sacrificial substrate formed of a silicon wafer or the like. The sacrificial substrate may be removed in a subsequent process.

The preliminary stack structure 200 may include a plurality of first material layers 201 and a plurality of second material layers 203 extended in the plane (for example, the XY plane). The plurality of first material layers 201 may be alternately stacked with the plurality of second material layers 203 in the third direction (for example, the Z-axis direction) that is substantially perpendicular to the plane. The preliminary stack structure 200 may include a first area AR1, a second area AR2, and a third area AR3. The first area AR1 corresponds to the cell array region CAR shown in each of FIGS. 4, 5A, and 5B. The second area AR2 may extend from the first area AR1 and correspond to the first contact area CTR1 shown in each of FIGS. 4, 5A, and 5B. The third area AR3 may extend from the second area AR2 and correspond to the second contact area CTR2 shown in each of FIGS. 4, 5A, and 5B.

The plurality of second material layers 203 may include a material having an etching selectivity with respect to the plurality of first material layers 201. In an embodiment, the plurality of first material layers 201 may include an insulating material and may form the first interlayer insulating layer IL1 and the second interlayer insulating layer IL2 as shown in FIGS. 5A and 5B. The plurality of first material layers 201 may include a silicon oxide layer, a silicon oxynitride layer, and the like. The plurality of second material layers 203 may include an insulating material and may form the sacrificial insulating layer SC as shown in FIGS. 5A and 5B. The plurality of second material layers 203 may include a silicon nitride layer.

Subsequently, a mask layer 301 may be formed over the preliminary stack structure 200. The mask layer 301 may include a material having an etching selectivity with respect to the uppermost first material layer 201 of the preliminary stack structure 200. In an embodiment, the mask layer 301 may include a silicon nitride layer or a silicon layer.

Subsequently, a channel hole penetrating the mask layer 301 and the preliminary stack structure 200 may be formed through a photolithography process and an etching process. The channel hole may penetrate the preliminary stack structure 200 in the first area AR1. Although not shown in the drawing, the channel hole may extend into the lower structure. Subsequently, a process of forming a memory layer 261 along a surface of the channel hole, a process of forming a first semiconductor layer along a surface of memory layer 261, and a process of filling the center region of the channel hole defined by the first semiconductor layer with a core insulating layer 265 and a second semiconductor layer may be performed. After the conductive impurities are injected into the second semiconductor layer, an annealing process for activating the conductive impurities may be performed. The first semiconductor layer and the second semiconductor layer may form a channel pillar 263. A portion of the first semiconductor layer interposed between the memory layer 261 and the core insulating layer 265 may form a channel layer 263A of the channel pillar 263, and the remaining portion of the first semiconductor layer and the second semiconductor layer may form a capping pattern 263B of the channel pillar 263.

A plurality of openings penetrating the mask layer 301 and the preliminary stack structure 200 may be formed through a separate photolithography process and etching process that are distinct from the process of forming the channel hole. The plurality of openings may include a first opening for the support structure 269 and a second opening for a vertical insulating layer 270. The second opening may penetrate the preliminary stack structure 200 in the third area AR3. Subsequently, by filling the plurality of openings with an insulating material, the support structure 269 in the first opening and the vertical insulating layer 270 in the second opening may be formed.

A separate photolithography process and etching process, apart from the process of forming the channel hole and the process of forming the plurality of openings, may be used to form a peripheral contact hole penetrating the mask layer 301 and the preliminary stack structure 200. Subsequently, by filling the peripheral contact hole with a conductive material, a peripheral circuit contact structure 271 in the peripheral contact hole may be formed.

Referring to FIG. 6B, an opening OP penetrating the vertical insulating layer 270 may be formed through a photolithography process and an etching process. Although not shown in the drawing, the lower structure may be exposed by the opening OP. In an embodiment, the first and second source level contacts 159A and 159B, shown in FIG. 5A, and a portion of the source level insulating layer 157 therebetween may be exposed by the opening OP. In an embodiment, the sacrificial substrate may be exposed by the opening OP. The vertical insulating layer 270 may remain to cover a sidewall of the preliminary stack structure 200.

Referring to FIG. 6C, an electrode layer 272 may be formed along a surface of the opening OP. The electrode layer 272 may extend from a sidewall of the opening OP to a bottom surface of the opening OP. The electrode layer 272 may include various conductive materials.

Referring to FIG. 6D, the electrode layer 272, shown in FIG. 6C, may be partially removed through an etching process. As a result, the electrode layer may be separated into a first capacitor electrode 272A and a second capacitor electrode 272B.

Referring to FIG. 6E, an empty space of the opening OP between the first capacitor electrode 272A and the second capacitor electrode 272B, shown in FIG. 6D, may be filled with a capacitor dielectric layer 273. Thus, a capacitor structure including the first capacitor electrode 272A, the second capacitor electrode 272B, and the capacitor dielectric layer 273 may be formed.

The method of forming the capacitor structure is not limited to the above. Although not shown in the drawing, in an embodiment, after a first trench and a second trench are formed to penetrate the vertical insulating layer 270 shown in FIG. 6A, the first and second trenches are respectively filled with the first capacitor electrode 272A and the second capacitor electrode 272B, thereby forming the capacitor structure. In such case, a portion of the vertical insulating layer between the first trench and the second trench may serve as the capacitor dielectric layer 273.

Referring to FIG. 6F, the mask layer 301, shown in FIG. 6E, may be removed. Subsequently, an insulating structure 275 may be formed to cover the channel pillar 263, the support structure 269, the vertical insulating layer 270, the first capacitor electrode 272A, the second capacitor electrode 272B, the capacitor dielectric layer 273, the peripheral circuit contact 271, and the preliminary stack structure 200 as shown in FIG. 6E.

Subsequently, a portion of each of the plurality of second material layers 203 of the preliminary stack structure 200, shown in FIG. 6E, may be replaced with a plurality of conductive layers 276. To this end, slits may be formed through a photolithography process and an etching process. Although not shown in the drawing, the slits may be formed with the same layout as the gate isolation structures GS as shown in FIG. 4 and may be formed to penetrate the insulating structure 275 and the preliminary stack 200 as shown in FIG. 6E. The slits may be used as a path to replace a portion of each of the plurality of second material layers 203, shown in FIG. 6E, with the plurality of conductive layers 276.

The plurality of conductive layers 276 and a portion of the plurality of first material layers 201, alternately disposed in the third direction (for example, a Z-axis direction) therewith, may form a gate stack structure 200G. The plurality of second material layers 203 and another portion of the plurality of first material layers 201, alternately disposed in the third direction therewith, may form a dummy stack structure 200D. During the process of replacing a portion of each of the plurality of second material layers 203 with the plurality of conductive layers 276, the vertical insulating layer 270 may serve as a barrier to block another portion of each of the plurality of second material layers 203, forming the dummy stack structure 200D, from being replaced with the plurality of conductive layers 276.

Subsequently, although not shown in the drawing, the slits formed by the layout of the gate isolation structures GS shown in FIG. 4 may be filled with insulating materials, conductive materials, semiconductor materials, or the like. In addition, the select line isolation structure SS, shown in FIG. 4, may be formed so that at least one conductive layer, among the plurality of conductive layers 276, penetrates.

Referring to FIG. 6G, a gate contact structure 277GC may be formed to penetrate the insulating structure 275. The gate contact structure 277GC may penetrate the first material layer 201 to be in contact with a corresponding conductive layer, among the plurality of conductive layers 276. The gate contact structure 277GC may have various structures in addition to the structures illustrated in the drawings and may be in contact with the corresponding conductive layer.

Subsequently, subsequent processes, such as forming a bit line connection structure 277BC and via contacts 277V1, 277V2, and 277V3 that penetrate the insulating structure 275 may be performed.

The first capacitor electrode 272A and the second capacitor electrode 272B, according to an embodiment of the present disclosure, may be formed to penetrate the vertical insulating layer 270 after forming the vertical insulating layer 272 penetrating the preliminary stack structure of the plurality of first material layers 201 and the plurality of second material layers 203. The number of stacked second material layers 203 may correspond to the number of stacked conductive layers 276. The number of stacked conductive layers 276 may be increased so that the degree of integration of memory cells of the semiconductor memory device is improved, and to this end, the number of stacked second material layers 203 may be increased. According to an embodiment of the present disclosure, because the facing area between the first capacitor electrode 272A and the second capacitor electrode 272B increases in proportion to the number of stacked layers of the plurality of second material layers 203, the capacitance of the capacitor structure may be stably secured.

According to embodiments of the present disclosure, a capacitor structure is disposed to penetrate a vertical insulating layer disposed between a dummy stack structure and a gate stack structure, so that the arrangement space of the capacitor structure may be secured within a limited area.

According to embodiments of the present disclosure, the capacitance of a capacitor may be increased in proportion to an increase in the number of stacked conductive layers of the gate stack structure, thereby improving the operation reliability of the semiconductor memory device.

What is claimed is:

1. A semiconductor memory device, comprising:
a gate stack structure including a plurality of conductive layers, the plurality of conductive layers extending in a plane based on a first direction and a second direction and stacked to be spaced apart from each other in a third direction crossing the plane;
a dummy stack structure spaced apart from the gate stack structure in the plane;
a vertical insulating layer interposed between the gate stack structure and the dummy stack structure; and
a capacitor structure including a first capacitor electrode and a second capacitor electrode, the first capacitor electrode and the second capacitor electrode penetrating the vertical insulating layer and extending parallel to each other.

2. The semiconductor memory device of claim 1, wherein the dummy stack structure includes:
a plurality of sacrificial insulating layers respectively disposed at substantially the same levels as the plurality of conductive layers; and
a plurality of interlayer insulating layers alternately disposed with the plurality of sacrificial insulating layers in the third direction.

3. The semiconductor memory device of claim 1, wherein the vertical insulating layer surrounds a capacitor region, and
wherein the first capacitor electrode and the second capacitor electrode extend along a boundary of the capacitor region.

4. The semiconductor memory device of claim 1, wherein the capacitor structure further includes a capacitor dielectric layer interposed between the first capacitor electrode and the second capacitor electrode.

5. The semiconductor memory device of claim 1, further comprising a plurality of peripheral circuit contact structures penetrating the dummy stack structure and disposed to be spaced apart from each other in the first direction and the second direction in the plane.

6. The semiconductor memory device of claim 1, further comprising:
a source layer overlapping with the gate stack structure in the third direction;
a source level insulating layer overlapping with the dummy stack structure in the third direction;
an insulating structure covering the gate stack structure, the dummy stack structure, and the capacitor structure;
a first capacitor via contact and a second capacitor via contact penetrating the insulating structure to be coupled to the first capacitor electrode and the second capacitor electrode, respectively; and
a first source level contact and a second source level contact penetrating the source level insulating layer to be coupled to the first capacitor electrode and the second capacitor electrode, respectively.

7. A semiconductor memory device, comprising:
a dummy stack structure including a plurality of sacrificial insulating layers extending in a plane based on a first direction and a second direction, and the plurality of sacrificial insulating layers stacked to be spaced apart from each other in a third direction crossing the plane;
a vertical insulating layer extending along a first sidewall, a second sidewall, and a third sidewall of the dummy stack structure, the first sidewall and the second sidewall facing opposite directions in the plane, the third sidewall coupling the first sidewall to the second sidewall;
a gate stack structure including a plurality of conductive layers surrounding the vertical insulating layer in the plane and stacked to be spaced apart from each other in the third direction; and
a capacitor structure penetrating the vertical insulating layer between the third sidewall of the dummy stack structure and the gate stack structure.

8. The semiconductor memory device of claim 7, wherein the gate stack structure further includes a plurality of first interlayer insulating layers alternately disposed with the plurality of conductive layers in the third direction, and
wherein the dummy stack structure further includes a plurality of second interlayer insulating layers alternately disposed with the plurality of sacrificial insulating layers in the third direction.

9. The semiconductor memory device of claim 8, wherein the plurality of sacrificial insulating layers are disposed at substantially the same levels as the plurality of conductive layers, respectively, and
wherein the plurality of second interlayer insulating layers are disposed at substantially the same levels as the plurality of first interlayer insulating layers, respectively.

10. The semiconductor memory device of claim 7, wherein the gate stack structure includes a cell array region, a first contact region extending from the cell array region toward the third sidewall, and a second contact region extending parallel to each of the first sidewall and the second sidewall from the first contact region.

11. The semiconductor memory device of claim 10, further comprising:
a channel pillar penetrating the plurality of conductive layers of the gate stack structure in the cell array region; and
a memory layer interposed between the channel pillar and the gate stack structure.

12. The semiconductor memory device of claim 7, wherein the capacitor structure includes a first capacitor electrode, a second capacitor electrode, and a capacitor dielectric layer disposed in a capacitor region surrounded by the vertical insulating layer.

13. The semiconductor memory device of claim 12, wherein the first capacitor electrode is disposed closer to the gate stack structure than the dummy stack structure,
wherein the second capacitor electrode is disposed closer to the dummy stack structure than the gate stack structure, and
wherein the capacitor dielectric layer is disposed between the first capacitor electrode and the second capacitor electrode.

14. The semiconductor memory device of claim 7, further comprising:
a source layer overlapping with the gate stack structure in the third direction;
a source level insulating layer overlapping with the dummy stack structure in the third direction;
an insulating structure covering the gate stack structure, the dummy stack structure, and the capacitor structure;
a capacitor via contact penetrating the insulating structure and coupled to an electrode of the capacitor structure; and
a source level contact penetrating the source level insulating layer and coupled to the electrode of the capacitor structure.

15. The semiconductor memory device of claim 7, further comprising a peripheral circuit contact structure penetrating the dummy stack structure.
